(19) United States
(12) Patent Application Publication
(10) Pub. No.: US 2010/0123176 A1
(43) Pub. Date: May 20, 2010

(54) SEMICONDUCTOR MEMORY DEVICE

(75) Inventor: Jun Nishimura, Yokohama-Shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/563,545

(22) Filed: Sep. 21, 2009

(30) Foreign Application Priority Data
Nov. 18, 2008 (JP) 2008-294569

(51) Int. Cl. H01L 27/115

(52) U.S. Cl. 257/295; 257/E27.104

(57) ABSTRACT

A semiconductor memory device has a plurality of first cell selection MOS transistors of a first conductivity type formed on a first element region and connected in series between a bit line and a plate line; a plurality of first ferroelectric capacitors connected to the first cell selection MOS transistors in parallel in one-to-one correspondence; a plurality of second cell selection MOS transistors of the first conductivity type formed on a second element region and connected in series between a bit line and a plate line; and a plurality of second ferroelectric capacitors connected to the second cell selection MOS transistors in parallel in one-to-one correspondence, wherein the first ferroelectric capacitors and the second ferroelectric capacitors are disposed alternately on the first element region and the second element region in the first direction.

### CROSS-REFERENCE TO RELATED APPLICATION

This application is based upon and claims the benefit of priority from the prior Japanese Patent Application No. 2008-294569, filed on Nov. 18, 2008, the entire contents of which are incorporated herein by reference.

### BACKGROUND OF THE INVENTION

1. Field of the Invention

The present invention relates to a semiconductor memory device, which is applied to a ferroelectric random access memory (FeRAM).

2. Background Art

In recent years, the ferroelectric random access memory (FeRAM) using a ferroelectric capacitor has drawn attention as one of non-volatile semiconductor memories.

As regards the ferroelectric random access memory, a three-dimensional cell structure in which a ferroelectric film is disposed between wall-shaped electrodes formed on a source-drain diffusion layer of a selection transistor and a plate capacitor parallel to the transistor is formed on the gate electrode of the transistor is proposed to address the area penalty (see, for example, Japanese Patent Laid-Open No. 2005-530355).

### SUMMARY OF THE INVENTION

According to one aspect of the present invention, there is provided: a semiconductor memory device comprising:

a plurality of first cell selection Metal Oxide Semiconductor (MOS) transistors of a first conductivity type formed on a first element region and connected in series between a bit line and a plate line, the first element region being sandwiched between element isolation regions formed on a semiconductor substrate and extending in a first direction, the first element region being extended in the first direction;

a plurality of first ferroelectric capacitors connected to the first cell selection MOS transistors in parallel in one-to-one correspondence, the first ferroelectric capacitor comprising a first ferroelectric film formed over the first element region via an interlayer insulation film, a first bottom electrode electrically connected to a source diffusion layer of the first cell selection MOS transistor and formed under the first ferroelectric film, and a first top electrode electrically connected to a drain diffusion layer of the first cell selection MOS transistor and formed over the first ferroelectric film;

a plurality of second cell selection MOS transistors of the first conductivity type formed on a second element region and connected in series between a bit line and a plate line, the second element region being sandwiched between element isolation regions formed on the semiconductor substrate and extending in the first direction, the second element region being extended in the first direction and being adjacent to the first element region; and

a plurality of second ferroelectric capacitors connected to the second cell selection MOS transistors in parallel in one-to-one correspondence, the second ferroelectric capacitor comprising a second ferroelectric film formed over the second element region via an interlayer insulation film, a second bottom electrode electrically connected to a source diffusion layer of the second cell selection MOS transistor and formed under the second ferroelectric film, and a second top electrode electrically connected to a drain diffusion layer of the second cell selection MOS transistor and formed over the second ferroelectric film,

wherein the first ferroelectric capacitors and the second ferroelectric capacitors are disposed alternately on the first element region and the second element region in the first direction.

### BRIEF DESCRIPTION OF THE DRAWINGS

FIG. 1 is a circuit diagram showing an example of a circuit configuration of a memory cell in a semiconductor memory device 100 according to a first embodiment of the present invention;

FIG. 2 is a plan view of a schematic pattern with attention paid to vicinity of periphery of ferroelectric capacitors in the memory cell of the semiconductor memory device 100 according to the first embodiment of the present invention;

FIG. 3 is a sectional view showing an A-A section of the semiconductor memory device 100 shown in FIG. 2;

FIG. 4 is a sectional view showing a B-B section of the semiconductor memory device 100 shown in FIG. 2;

FIG. 5 is a diagram for explaining the size of the memory cells in the semiconductor memory device 100 shown in FIG. 2;

FIG. 6A is a diagram showing relation between voltages applied to electrodes of the ferroelectric capacitors in the semiconductor memory device 100 according to the first embodiment at the time of writing;

FIG. 6B is a diagram showing relation between voltages applied to electrodes of the ferroelectric capacitors in the semiconductor memory device 100 according to the first embodiment at the time of writing;

FIG. 7 is a plan view of a schematic pattern with attention paid to vicinity of periphery of ferroelectric capacitors in a memory cell of a semiconductor memory device 200 according to the second embodiment of the present invention; and

FIG. 8 is a diagram showing relations between the voltage applied to the ferroelectric capacitor (ferroelectric film) and the polarization of the ferroelectric substance.

### DETAILED DESCRIPTION

### Comparative Example

For example, in the conventional chain type ferroelectric random access memory, there is a problem that dispersion in characteristics is large between adjacent memory cells.

In the chain type ferroelectric random access memory according to the conventional technique, the voltage application direction to the memory cell differs between adjacent memory cells. For example, in writing into a certain memory cell, the lower electrode becomes higher in potential than the upper electrode. On the other hand, in writing into another memory cell adjacent to the memory cell, the lower electrode becomes lower in potential than the upper electrode.

The above-described dispersion in characteristics is considered to be caused by that the direction (polarity) of voltage application to a memory cell is different between adjacent memory cells.

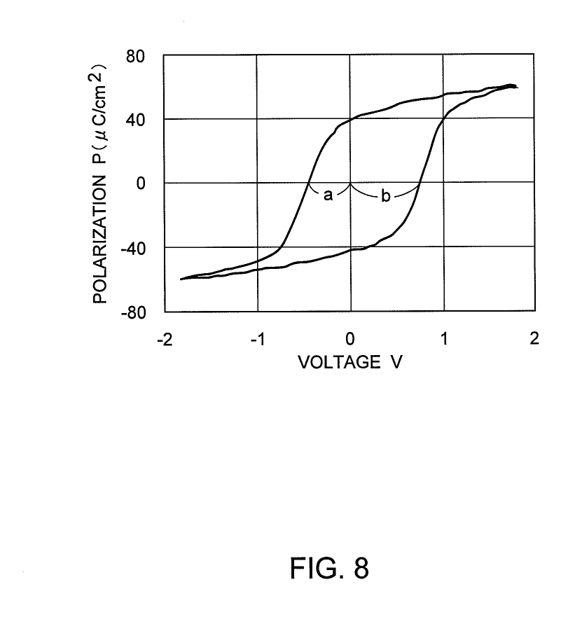

FIG. 8 is a diagram showing relations between the voltage applied to the ferroelectric capacitor (ferroelectric film) and the polarization of the ferroelectric substance.

If a voltage is applied from a bit line to a plate line, then a signal quantity at this time depends upon parasitic capacitance and the PV hysteresis of the ferroelectric substance (FIG. 8). In this case, a defective mode called imprint in which the voltage (coercive electric field) at which P becomes zero in characteristics of the ferroelectric substance becomes bilaterally non-symmetrical (a≠b in FIG. 8) is observed.

This defective mode is considered to be caused by that the ferroelectric film and the electrode surrounding it are asymmetrical between the upper part and the lower part (the interface between the ferroelectric film and the electrode is different).

In this way, a phenomenon that signal quantities of two adjacent memory cells differ from each other occurs and the dispersion of signal quantity is made large.

In embodiments according to the present invention, a configuration of a semiconductor memory device for which it is possible to reduce the defective modes and reduce the area of the circuit without changing the structure of the ferroelectric capacitor itself is proposed.

Hereinafter, embodiments according to the present invention will be described with reference to the drawings.

### First Embodiment

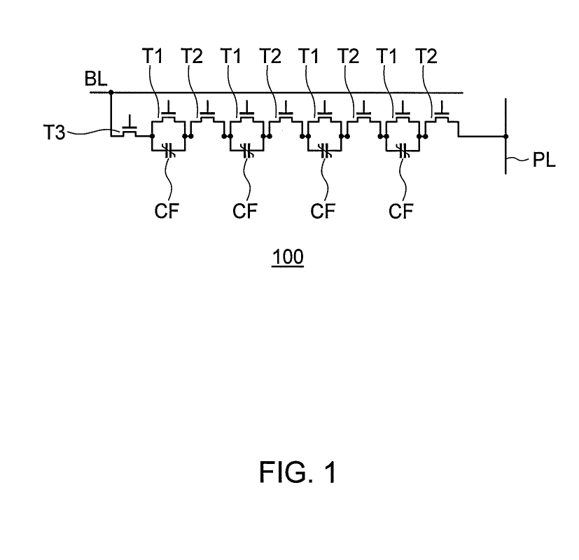

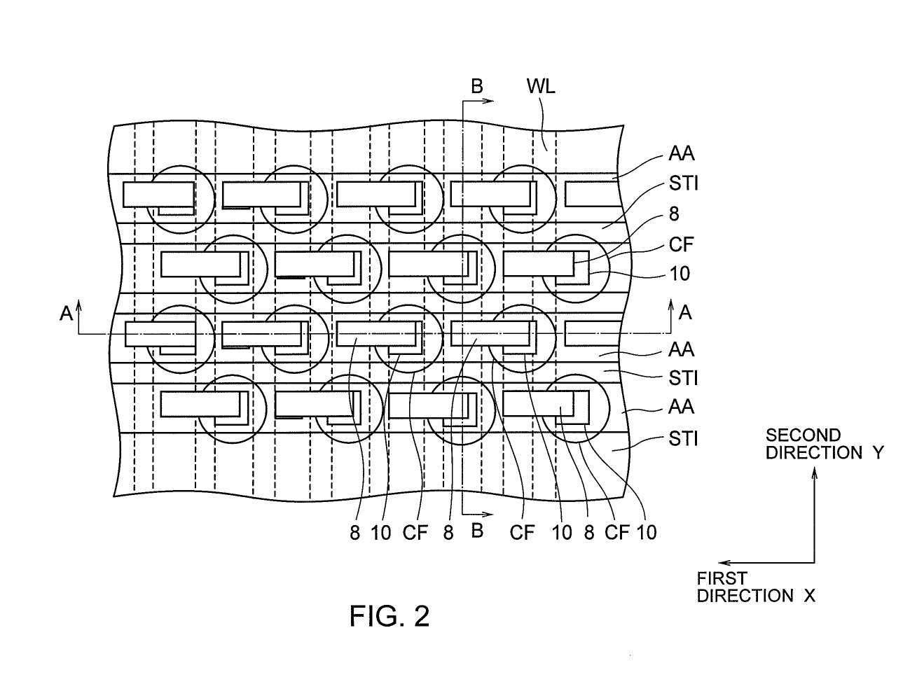

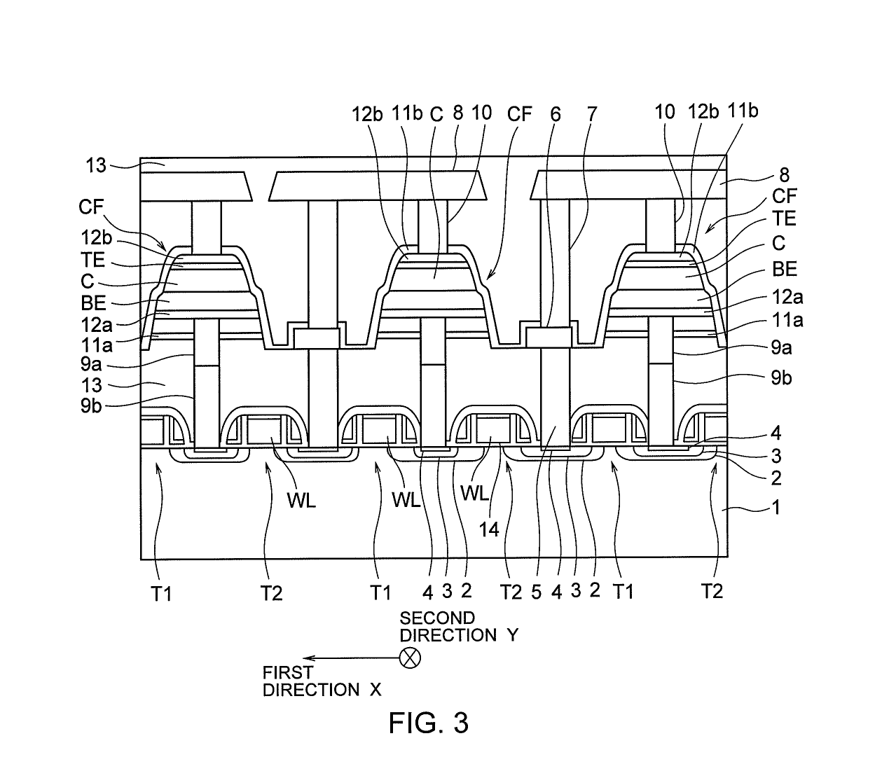

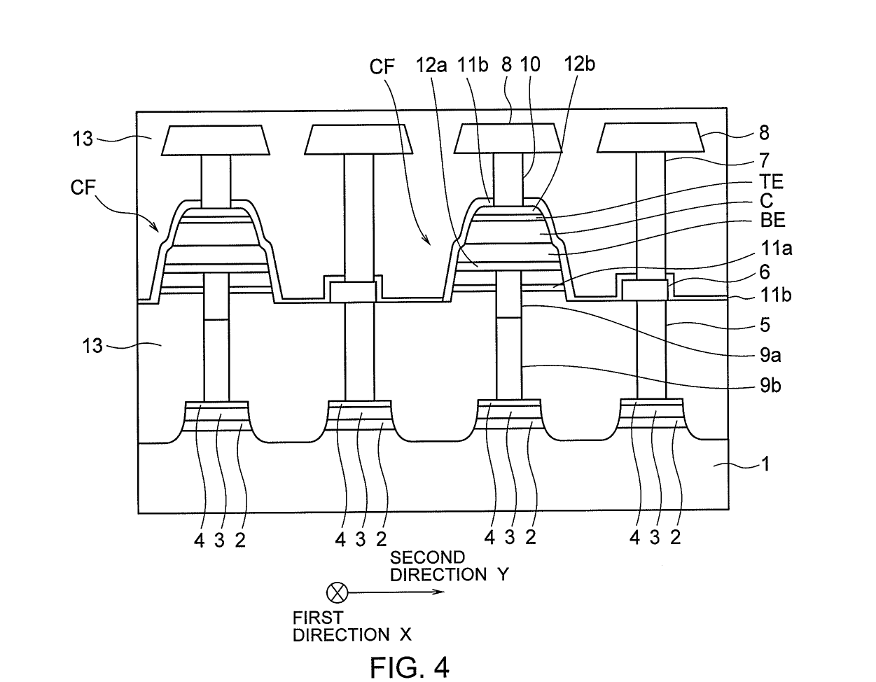

FIG. 1 is a circuit diagram showing an example of a circuit configuration of a memory cell in a semiconductor memory device 100 according to a first embodiment of the present invention. FIG. 2 is a plan view of a schematic pattern with attention paid to vicinity of periphery of ferroelectric capacitors in the memory cell of the semiconductor memory device 100 according to the first embodiment of the present invention. FIG. 3 is a sectional view showing an A-A section of the semiconductor memory device 100 shown in FIG. 2. FIG. 4 is a sectional view showing a B-B section of the semiconductor memory device 100 shown in FIG. 2.

In the drawings, a first direction X is a direction of an element region AA, and a second direction Y perpendicular to the first direction X on a semiconductor substrate 1 is a direction of word line WL.

As shown in FIG. 1, the semiconductor memory device 100 includes a plurality of cell selection MOS transistors T1 and T2, a block selection MOS transistor T3, a bit line BL, a plate line PL, and a plurality of ferroelectric capacitors CF.

The cell selection MOS transistors T1 and T2 are connected in plurality in series between the bit line BL and the plate line PL. These cell selection MOS transistors T1 and T2 have the same conductivity type (which is n-type here, but which may also be p-type).

The ferroelectric capacitors CF are connected in parallel with the cell selection MOS transistors T1 in one-to-one correspondence between the bit line BL and the plate line PL.

Furthermore, the block selection MOS transistor T3 is provided between the bit line BL and a block formed of the ferroelectric capacitors CF and the cell selection MOS transistors T1 and T2. When the block selection MOS transistor T3 is turned on, conduction is obtained between the bit line BL and the block formed of the ferroelectric capacitors CF and the cell selection MOS transistors T1 and T2.

As shown in FIGS. 2 to 4, element isolation regions ST1 are formed on the semiconductor substrate 1 such as a silicon substrate so as to extend in the first direction X. Element regions AA are formed on the semiconductor substrate 1 so as to be sandwiched between the element isolation regions ST1 and extend in the first direction X.

The ferroelectric capacitors CF are disposed alternately on two adjacent element regions AA in the first direction X (FIG. 2). Each of the ferroelectric capacitors CF takes the shape of a circle in its section which is parallel to the substrate plane of the semiconductor substrate 1.

The cell selection MOS transistors T1 are formed on the element regions AA. The cell selection MOS transistors T1 are disposed alternately on two adjacent element regions AA in the first direction X (FIGS. 3 and 4).

The ferroelectric capacitors CF are formed over source diffusion layers 2 and 3 of the cell selection MOS transistors T1. The ferroelectric capacitors CF and the cell selection MOS transistors T1 constitute memory cells.

Each of the ferroelectric capacitors CF includes a ferroelectric film C, a bottom electrode BE, and a top electrode TE.

The ferroelectric film C is formed on the element region AA of the semiconductor substrate 1 via an interlayer insulation film 13. The ferroelectric film C is formed of, for example, a PZT (Pb(ZrₓTi₁₋ₓ)O₃) film, a BIT (Bi₄Ti₃O₁₂) film, a BLT film, an SBT (SrBi₂Ta₂O₉) film or the like.

The bottom electrode BE is electrically connected to the source diffusion layers 2 and 3 of the cell selection MOS transistor T1, and formed under the ferroelectric film C. In other words, the bottom electrode BE and the source diffusion layers 2 and 3 are connected via a silicide film 4, a contact plug 9b and a tungsten plug 9a. In addition, a tungsten barrier film 12a is formed between the bottom electrode BE and the tungsten plug 9a to prevent tungsten or the like from being diffused to the ferroelectric film C. The bottom electrode BE is formed of, for example, Ir.

The top electrode TE is electrically connected to drain diffusion layers 2 and 3 of the cell selection MOS transistor T1, and formed over the ferroelectric film C. In other words, the top electrode TE and the drain diffusion layers 2 and 3 are connected via a silicide film 4, contact plugs 5 to 7, metal interconnection 8, and a contact plug 10. In addition, a tungsten barrier film 12b is formed between the top electrode TE and the contact plug 10 to prevent tungsten or the like from being diffused to the ferroelectric film C. The top electrode TE is formed of, for example, IrO₂.

The top electrode TE and the bottom electrode BE are formed of different compositions. In other words, an interface between the ferroelectric film C and the top electrode TE is different from an interface between the ferroelectric film C and the bottom electrode BE. As a result, polarization characteristics of the ferroelectric capacitor CF are similar to those described earlier and shown in FIG. 8.

In addition, an SRO film (not shown) is formed between the bottom electrode BE and the ferroelectric film C and between the top electrode TE and the ferroelectric film C.

As described above, connection relations between the top electrode TE and the bottom electrode BE of the ferroelectric capacitor CF and the diffusion layers 2 and 3 of the cell selection MOS transistor T1 are the same in respective memory cells.

Owing to this arrangement of the memory cells (FIG. 3), it is possible to make directions (polarities) of voltages applied to ferroelectric capacitors CF adjacent in the first direction X (the direction of the element region AA) the same. As a result, influence of the mode defect caused by imprint as described above on the polarization characteristics of the ferroelectric capacitors CF is suppressed.

In addition, hydrogen barrier films 11a and 11b are formed around each of the ferroelectric capacitors CF to shield the ferroelectric film C from hydrogen or the like. The hydrogen barrier films 11a and 11b are formed of, for example, alumina films or the like.

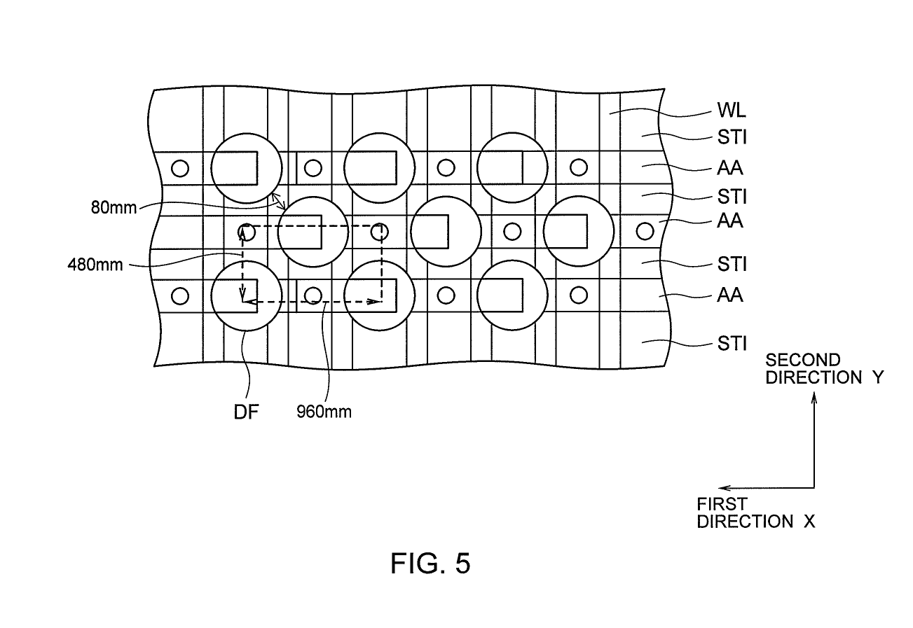

FIG. 5 is a diagram for explaining the size of the memory cells in the semiconductor memory device 100 shown in FIG. 2.

As shown in FIG. 5, the distance between ferroelectric capacitors CF formed on adjacent element regions AA is minimized in a direction inclined from the second direction Y (the direction of the word lines WL). Here, the distance between ferroelectric capacitors CF formed on adjacent element regions AA is, for example, 80 nm.

In this case, the area of the memory cells in the semiconductor memory device 100 can be reduced by, for example, approximately 25% as compared with the conventional art.

In the semiconductor memory device 100, the ferroelectric capacitor CF is made larger than the contact plug 10 in the section parallel to the substrate plane as shown in FIG. 2 (FIG. 5) in order to increase the capacity. In the first embodiment, therefore, the area of the circuit of the semiconductor memory device 100 can be made small by arranging the ferroelectric capacitors CF as described above.

Operation of the memory cells in the semiconductor memory device 100 having the above-described configuration will now be described.

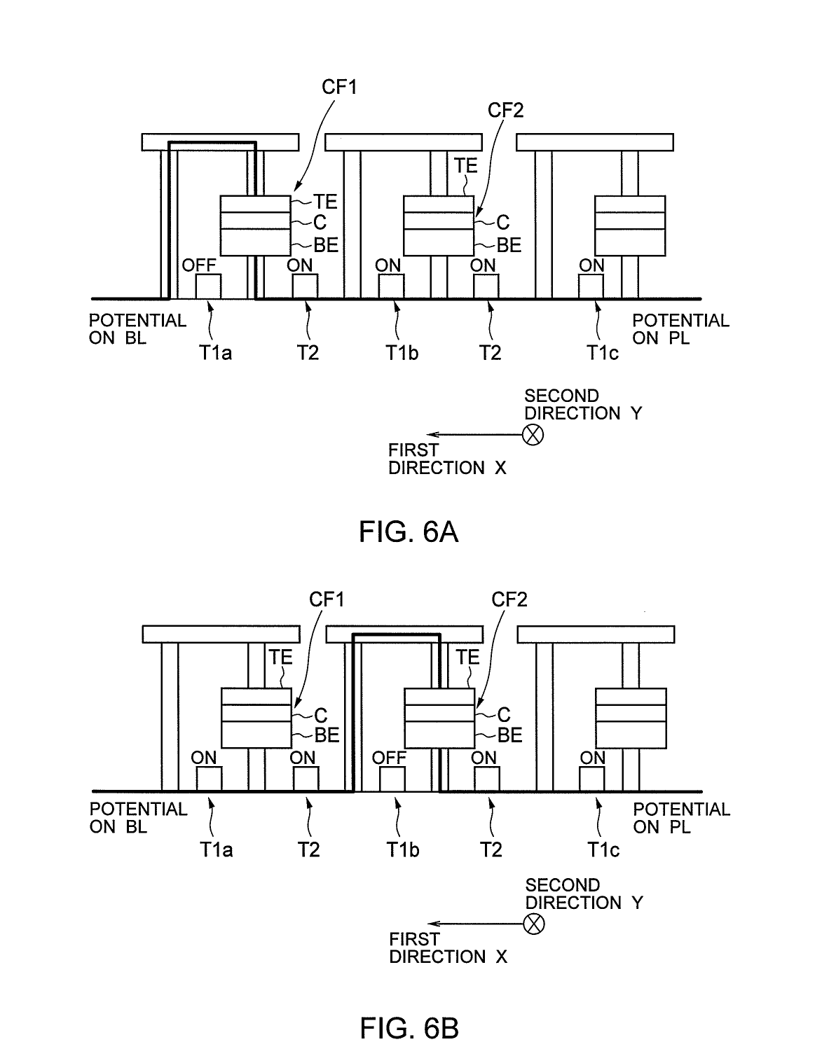

FIGS. 6A and 6B are diagrams showing relations between voltages applied to electrodes of the ferroelectric capacitors in the semiconductor memory device 100 according to the first embodiment at the time of writing. FIG. 6A shows a state in which writing is being conducted on a ferroelectric capacitor CF1. FIG. 6B shows a state in which writing is being conducted on a ferroelectric capacitor CF2 which is adjacent to the ferroelectric capacitor CF1 in the first direction X.

As shown in FIG. 6A, a cell selection MOS transistor Tia is selected (turned off) by a word line WL and a voltage is applied between a plate line PL and a bit line BL at the time of writing. As a result, a ferroelectric capacitor CF1 is polarized.

As shown in FIG. 6B, a cell selection MOS transistor Tib is selected (turned off) by the word line WL and a voltage is applied between the plate line PL and the bit line BL at the time of writing. As a result, a ferroelectric capacitor CF2 is polarized.

In these write operations, potential relations (polarities) applied to the ferroelectric capacitors CF1 and CF2 are the same. As a result, influence of the mode defect caused by imprint as described above on the polarization characteristics of the ferroelectric capacitors CF1 and CF2 is suppressed.

On the other hand, at the time of reading, one of cell selection MOS transistors T1a to T1c is selected (turned off) by the word line WL and a determination is made whether data is “1” or “0” depending on whether a current caused by polarization inversion flows between the plate line PL and the bit line BL.

In this way, influence of the mode defect caused by imprint as described above on the polarization characteristics of the ferroelectric capacitors can be suppressed.

According to the semiconductor memory device in the present embodiment, it is possible to reduce the area of the circuit while reducing the dispersion in polarization characteristics of the ferroelectric capacitors in the memory cells as heretofore described.

### Second Embodiment

In the first embodiment, the case where each of the ferroelectric capacitors takes the shape of a circle in section parallel to the substrate plane of the semiconductor substrate has been described.

However, the ferroelectric capacitor may have another shape in section parallel to the substrate plane of the semiconductor substrate.

In a second embodiment, therefore, the case where each of the ferroelectric capacitors takes the shape of a square in section parallel to the substrate plane of the semiconductor substrate will be described especially with due regard to reduction of the area of the circuit.

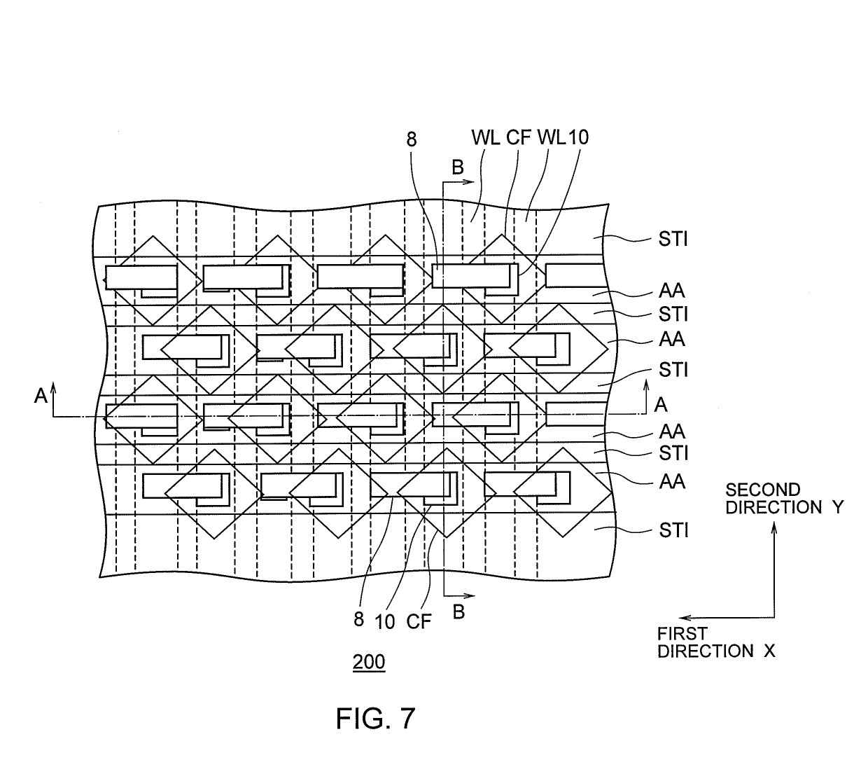

FIG. 7 is a plan view of a schematic pattern with attention paid to vicinity of periphery of ferroelectric capacitors in a memory cell of a semiconductor memory device 200 according to the second embodiment of the present invention. The semiconductor memory device 200 shown in FIG. 7 has a circuit configuration similar to that the semiconductor memory device 100 according to the first embodiment shown in FIG. 1. Sectional views of the semiconductor memory device 200 shown in FIG. 7 at an A-A section and a B-B section are similar to the sectional views of the semiconductor memory device 100 according to the first embodiment shown in FIGS. 2 and 3.

As shown in FIG. 7, each of ferroelectric capacitors CF takes the shape of a square having sides inclined by 45 degrees from the first direction X in section parallel to the substrate plane of the semiconductor substrate 1.

As a result, it is possible to make the distance between ferroelectric capacitors CF formed on adjacent element regions AA shorter while increasing the sectional area of each of the ferroelectric capacitors CF.

Other operations and functions of the semiconductor memory device 200 are similar to those of the semiconductor memory device 100 according to the first embodiment.

According to the semiconductor memory device in the present embodiment, it is possible to reduce the area of the circuit while reducing the dispersion in polarization characteristics of the ferroelectric capacitors in the memory cells as heretofore described.

What is claimed is:

1. A semiconductor memory device comprising:
a plurality of first cell selection Metal Oxide Semiconductor (MOS) transistors of a first conductivity type on a first element region and connected in series between a bit line and a plate line, the first element region extending in a first direction between element isolation regions extending in the first direction on a semiconductor substrate;
a plurality of first ferroelectric capacitors connected to the first cell selection MOS transistors in parallel in one-to-one correspondence, the first ferroelectric capacitor comprising a first ferroelectric film over the first element region via an interlayer insulation film, a first bottom electrode under the first ferroelectric film and electrically connected to a source diffusion layer of the first cell selection MOS transistor, and a first top electrode over the first ferroelectric film and electrically connected to a drain diffusion layer of the first cell selection MOS transistor;
a plurality of second cell selection MOS transistors of the first conductivity type on a second element region and connected in series between a bit line and a plate line, the second element region extending in the first direction, adjacent to the first element region, and between element isolation regions extending in the first direction on the semiconductor substrate; and
a plurality of second ferroelectric capacitors connected to the second cell selection MOS transistors in parallel in one-to-one correspondence, the second ferroelectric capacitor comprising a second ferroelectric film over the second element region via an interlayer insulation film, a second bottom electrode under the second ferroelectric film and electrically connected to a source diffusion layer of the second cell selection MOS transistor, and a second top electrode over the second ferroelectric film and electrically connected to a drain diffusion layer of the second cell selection MOS transistor,
wherein the first ferroelectric capacitors and the second ferroelectric capacitors are on the first element region and the second element region alternately in the first direction.

2. The semiconductor memory device of claim 1, wherein the first ferroelectric capacitors and the second ferroelectric capacitors comprise a circular shape in a portion parallel to a substrate plane of the semiconductor substrate.

3. The semiconductor memory device of claim 1, wherein the first ferroelectric capacitors and the second ferroelectric capacitors comprises a square shape comprising sides inclined by 45 degrees from the first direction in a portion parallel to the substrate plane of the semiconductor substrate.

4. The semiconductor memory device of claim 1, wherein the first cell selection MOS transistors and the second cell selection MOS transistors are on the first element region and the second element region alternately in the first direction.

5. The semiconductor memory device of claim 2, wherein the first cell selection MOS transistors and the second cell selection MOS transistors are on the first element region and the second element region alternately in the first direction.

6. The semiconductor memory device of claim 3, wherein the first cell selection MOS transistors and the second cell selection MOS transistors are on the first element region and the second element region alternately in the first direction.

7. The semiconductor memory device of claim 1, wherein the first ferroelectric capacitor is over the source diffusion layer of the first cell selection MOS transistor, and
the second ferroelectric capacitor is over the source diffusion layer of the second cell selection MOS transistor.

8. The semiconductor memory device of claim 2, wherein the first ferroelectric capacitor is over the source diffusion layer of the first cell selection MOS transistor, and
the second ferroelectric capacitor is over the source diffusion layer of the second cell selection MOS transistor.

9. The semiconductor memory device of claim 3, wherein the first ferroelectric capacitor is over the source diffusion layer of the first cell selection MOS transistor, and
the second ferroelectric capacitor is over the source diffusion layer of the second cell selection MOS transistor.

10. The semiconductor memory device of claim 4, wherein the first ferroelectric capacitor is over the source diffusion layer of the first cell selection MOS transistor, and
the second ferroelectric capacitor is over the source diffusion layer of the second cell selection MOS transistor.

11. The semiconductor memory device of claim 1, wherein a distance between the first ferroelectric capacitors and the second ferroelectric capacitors is minimized on the semiconductor substrate in a direction inclined from a second direction which is perpendicular to the first direction.

12. The semiconductor memory device of claim 2, wherein a distance between the first ferroelectric capacitors and the second ferroelectric capacitors is minimized on the semiconductor substrate in a direction inclined from a second direction which is perpendicular to the first direction.

13. The semiconductor memory device of claim 3, wherein a distance between the first ferroelectric capacitors and the second ferroelectric capacitors is minimized on the semiconductor substrate in a direction inclined from a second direction which is perpendicular to the first direction.

14. The semiconductor memory device of claim 4, wherein a distance between the first ferroelectric capacitors and the second ferroelectric capacitors is minimized on the semiconductor substrate in a direction inclined from a second direction which is perpendicular to the first direction.

15. The semiconductor memory device of claim 5, wherein a distance between the first ferroelectric capacitors and the second ferroelectric capacitors is minimized on the semiconductor substrate in a direction inclined from a second direction which is perpendicular to the first direction.

16. The semiconductor memory device of claim 1, wherein the first ferroelectric film and the second ferroelectric film are either a lead zirconate titanate (PZT) film, a bismuth titanium oxide (BIT) film, a bismuth lanthanum titanium oxide (BLT) film, or a strontium bismuth tantalum oxide (SBT) film.

17. The semiconductor memory device of claim 2, wherein the first ferroelectric film and the second ferroelectric film are either a PZT film, a BIT film, a BLT film, or an SBT film.

18. The semiconductor memory device of claim 3, wherein the first ferroelectric film and the second ferroelectric film are either a PZT film, a BIT film, a BLT film, or an SBT film.

19. The semiconductor memory device of claim 4, wherein the first ferroelectric film and the second ferroelectric film are either a PZT film, a BIT film, a BLT film, or an SBT film.

20. The semiconductor memory device of claim 7, wherein the first ferroelectric film and the second ferroelectric film are either a PZT film, a BIT film, a BLT film, or an SBT film.
